(19) United States
(12) Patent Application Publication
(10) Pub. No.: US 2024/0128227 A1
(43) Pub. Date: Apr. 18, 2024

(54) SIP-TYPE ELECTRONIC DEVICE AND METHOD FOR MAKING SUCH A DEVICE

(71) Applicant: COMMISSARIAT A L'ENERGIE ATOMIQUE ET AUX ENERGIES ALTERNATIVES, Paris (FR)

(72) Inventors: Perceval COUDRAIN, Grenoble Cedex 09 (FR); Arnaud GARNIER, Grenoble Cedex 09 (FR); Jeanne PIGNOL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/486,467

(22) Filed: Oct. 13, 2023

(30) Foreign Application Priority Data
Oct. 14, 2022 (FR) 22 10616

(51) Int. Cl. H01L 23/00; H01L 21/56; H01L 23/31; H01L 23/367; H01L 23/427; H01L 23/552

(52) U.S. Cl. CPC H01L 24/32; H01L 21/561; H01L 23/3128; H01L 23/367; H01L 23/427; H01L 23/552; H01L 24/19; H01L 24/20; H01L 24/27; H01L 24/29; H01L 24/83; H01L 24/96; H01L 21/568; H01L 2224/19; H01L 2224/211; H01L 2224/27845; H01L 2224/29082; H01L 2224/29144; H01L 2224/29147; H01L 2224/29166; H01L 2224/32225; H01L 2224/32245; H01L 2224/83005; H01L 2224/83193; H01L 2224/83201; H01L 2224/83895; H01L 2224/83948; H01L 2224/95001; H01L 2224/96; H01L 2924/20105; H01L 2924/20106; H01L 2924/20107; H01L 2924/20108; H01L 2924/20109

(57) ABSTRACT

A SiP-type electronic device, including an electronic chip provided with an electrical interconnection face; a redistribution layer electrically coupled to the electrical interconnection face of the chip; electrical connection elements electrically coupled to the chip by the redistribution layer which is arranged between the chip and the connection elements; a first metal layer arranged on the side of a second face of the chip and secured to this second face; an encapsulation material arranged around the chip, between the redistribution layer and the first metal layer; a second metal layer including a first face secured by direct bonding to the first metal layer; a substrate arranged against a second face of the second metal layer.

### TECHNICAL FIELD

The invention relates to the field of packaging, or encapsulation, of electronic chips to make SiP (“System-in-Package” type, in particular FOWLP (“Fan Out Wafer Level Packaging”) type, electronic devices.

### PRIOR ART

FOWLP packaging has become the standard, in particular for the integration of SiP-type electronic chips. In this packaging type, the interconnection pads of the chips, which are located on the side of an interconnection face of each chip, are interconnected, via one or more redistribution layer(s) formed against the interconnection faces of the chips, to interconnection elements with larger dimensions than the interconnection pads of the chips and distributed over a larger surface than that of the interconnection face of each chip. For example, these interconnection elements correspond to microbeads made of a meltable material. The electronic chips are further encapsulated in an encapsulation resin.

A critical point of this packaging type is the heat dissipation which should be done to evacuate the heat produced by the electronic chips. Existing solutions for achieving this heat dissipation involve external heat sinks, active or passive, affixed on the encapsulation material or directly on the chips, at the end of the packaging process. A thermal interface material, such as thermal glue or paste, is arranged between the heat sinks and the encapsulation material, or directly between the heat sinks and the chips, to enable assembly thereof and ensure the best possible contact while filling the unevenesses present between the heat sinks and the chips or the encapsulation material. Nonetheless, these solutions are expensive because the heat sinks are not collectively coupled to the chips but individually. In addition, the obtained heat dissipation performances are not optimum because the used thermal interface material limits thermal conduction between the chips and the heat sinks.

### DISCLOSURE OF THE INVENTION

The present invention aims to provide a SiP-type electronic device suited for FOWLP-type packaging, which does not require the use of a thermal interface material and improving the obtained heat dissipation performances.

For this purpose, a SiP-type electronic device is provided, comprising at least:
an electronic chip provided with an electrical interconnection face;
a redistribution layer electrically coupled to the electrical interconnection face of the electronic chip;
electrical connection elements electrically coupled to the electronic chip by the redistribution layer which is arranged between the electronic chip and the electrical connection elements;
a first metal layer arranged on the side of a second face of the electronic chip, opposite to the electrical interconnection face, and secured to the second face of the electronic chip;
an encapsulation material arranged around the electronic chip, between the redistribution layer and the first metal layer;
a second metal layer comprising a first face secured by direct bonding to the first metal layer;
a substrate arranged against a second face, opposite to the first face, of the second metal layer.

In this device, the heat sink is filled by the substrate which is secured to the electronic chip and to the encapsulation material via the first and second metal layers which are, themselves, secured against one another by direct bonding. Hence, this structure does not involve a thermal interface material, such as a thermal glue or paste, to ensure the connection between the heat-dissipating element and the chip. Consequently, this considerably improves the heat dissipation achieved within the device to evacuate heat generated by the electronic chip since the thermal connection formed by the first and second metal layers is better than that obtained using a thermal interface material such as a thermal glue or paste.

In a particular embodiment, the first and second metal layers may include copper and/or gold.

In one variant, each of the first and second metal layers may include a copper layer and a gold layer arranged against one another, the gold layers may be secured by direct bonding against one another. An advantage of this variant is that the temperature of implementation of the Au—Au direct bonding is lower than that of a Cu—Cu direct bonding. In this variant, each of the first and second metal layers may include an additional layer forming a diffusion barrier interposed between the copper layer and the gold layer, which allows limiting a potential interdiffusion between the copper and gold layers and thus limiting the risks of creation of holes or weakening of the structure over time. For example, such an interdiffusion layer may include TiN or Ni and have a thickness comprised between 5 nm and 50 nm.

In any case, the first and second metal layers are made such that their roughness is low enough to enable direct bonding therebetween, this low roughness may be obtained either directly when making the first and second metal layers, or after flattening the first and second metal layers.

According to different advantageous configurations, the substrate may include at least one amongst the following materials: silicon, SiC, Cu, CuMo, CuW, AlN, AlSiC, and/or the substrate may include at least one integrated vapor chamber, and/or the substrate may include structures promoting heat exchanges with the external environment. For example, the structures may correspond to trenches etched through a portion of the thickness of the substrate, and/or may be used for a heat-transfer fluid circulation. The electrical connection element may be distributed over a portion of the redistribution layer whose surface is larger than that of the electrical interconnection face of the electronic chip.

The substrate may be electrically coupled to the electronic chip, for example to gain weight to the electronic chip, and/or the substrate may further comprise at least one electromagnetic shielding layer.

The invention also relates to a method for making a SiP-type electronic device, comprising at least:
affixing an electronic chip over a first substrate such that an electrical interconnection face of the electronic chip is arranged on the side of the first substrate;
encapsulating the electronic chip in an encapsulation material;
making at least one first metal layer over the encapsulation material and the electronic chip;
making at least one second metal layer over a second substrate;
directly bonding the first and second metal layers against one another;
detaching the first substrate off the electronic chip and the encapsulation material;
making at least one redistribution layer electrically coupled to the electrical interconnection face of the electronic chip;
making electrical interconnection elements over the redistribution layer such that the electrical interconnection elements are electrically coupled to the electronic chip by the redistribution layer.

This method forms a heat dissipation solution integrated with the packaging process and which does not involve thermal interface materials.

The method may be such that:
making the first metal layer includes at least depositing a first copper layer over the encapsulation material and the electronic chip, and
making the second metal layer includes at least depositing a second copper layer over the second substrate.

In this case, directly bonding the first and second metal layers against one another may correspond to directly bonding the first and second copper layers against one another. Alternatively, the method may be such that:
making the first metal layer further includes depositing a first gold layer over the first copper layer, and
making the second metal layer further includes depositing a second gold layer over the second copper layer, and
directly bonding the first and second metal layers against one another corresponds to directly bonding the first and second gold layers against one another.

Optionally, flattening the first and second copper layers may be implemented before depositing the first and second gold layers.

Furthermore, in this variant, making the first copper layer may be followed by depositing a first diffusion barrier layer over the first copper layer, the first gold layer being deposited afterwards over the first diffusion barrier layer. Similarly, making the second copper layer may be followed by depositing a second diffusion barrier layer over the second copper layer, the second gold layer being deposited afterwards over the second diffusion barrier layer.

In another variant, the method may be such that:
making the first metal layer includes at least depositing a first gold layer over the encapsulation material and the electronic chip, and
making the second metal layer includes at least depositing a second gold layer over the second substrate.

The method may further include, between making the second metal layer and directly bonding the first and second metal layers, flattening the first metal layer and/or the second metal layer. This flattening may be implemented to achieve a low roughness of the metal layers if this low roughness is not obtained directly when making the metal layers.

The encapsulation of the electronic chip may include at least depositing the encapsulation material over the electronic chip, then flattening the encapsulation material.

Several electronic chips may be affixed simultaneously over the first substrate such that an electrical interconnection face of each of the electronic chips is arranged on the side of the first substrate, and the other steps of the method may be collectively implemented for all electronic chips, and the method may further include, after making of the electrical interconnection elements, a step of cutting the obtained structure so as to obtain several distinct SiP-type electronic devices each including one or more electronic chip(s). In this case, the completed collective packaging allows reducing the cost related to the implementation of the heat dissipation function within the packaging.

In this case, when the electronic chips have different thicknesses, flattening the encapsulation material may be stopped at the electronic chip(s) having the largest thickness. Alternatively, when the electronic chips have different thicknesses, these chips may be affixed on the first substrate such that the upper faces of these chips (faces opposite to those located on the side of the first substrate) are substantially aligned in the same plane.

The method may further include, after making the electrical interconnection elements, etching the second substrate forming structures promoting heat exchanges with the external environment, and/or the second substrate may include at least one integrated vapor chamber.

Throughout the document, the term “over” is used without distinction with regards to the spatial orientation of the element to which this term refers. For example, in the feature “over a face of the first substrate”, this face of the first substrate is not necessarily oriented upwards but may correspond to a face oriented according to any direction. Furthermore, the arrangement of a first element over a second element should be understood as being able to correspond to the arrangement of the first element directly against the second element, without any intermediate element between the first and second elements, or as being able to correspond to the arrangement of the first element over the second element with one or more intermediate element(s) arranged between the first and second elements.

### BRIEF DESCRIPTION OF THE DRAWINGS

The present invention will be better understood upon reading the description of embodiments given for merely indicative and non-limiting purposes with reference to the appended drawings wherein:

FIGS. 1 to 8 show the steps of a method for packaging electronic chips, object of the present invention, according to a particular embodiment;

FIGS. 9 to 11 show different variants of electronic devices, object of the present invention.

Identical, similar or equivalent portions of the different figures described hereinafter bear the same reference numerals so as to facilitate switching from one figure to another. The different portions shown in the figures are not necessarily plotted according to a uniform scale, to make the figures more readable.

The different possibilities (variants and embodiments) should be understood as not exclusive of each other and could be combined together.

### DETAILED DISCLOSURE OF PARTICULAR EMBODIMENTS

A method for packaging electronic chips 100 according to a particular embodiment is described hereinbelow with reference to FIGS. 1 to 8.

First of all, the electronic chips 100 to be packaged are affixed on a first substrate 102. Each of the chips 100 includes an electrical interconnection face arranged on the side of the first substrate 102 and at which interconnection pads 104 are for example located. For example, the first substrate 102 includes a semiconductor, glass, metal, or any other suitable material.

In the example of FIGS. 1 to 8, only two electronic chips 100 are shown. Nonetheless, the method may be collectively implemented for a larger number of electronic chips, or for one single chip.

During the packaging method, the first substrate 102 will be intended to be detached off the chips 100. In order to facilitate this detachment, it is possible to interpose, between the chips 100 and the first substrate 102, a layer 106 having, at room temperature, adhesive properties, these properties disappear when the layer 106 is heated up to a given temperature. For example, this layer 106 may correspond to a “REVALPHA” type layer commercialized by the company Nitto. Alternatively, this layer 106 may have adhesive properties degraded when illuminated, for example when it is exposed to an UV radiation. In this case, the first substrate 102 is selected such that it is transparent to the light radiation that will be used to degrade the adhesive properties of the layer 106, for example glass- or sapphire-based.

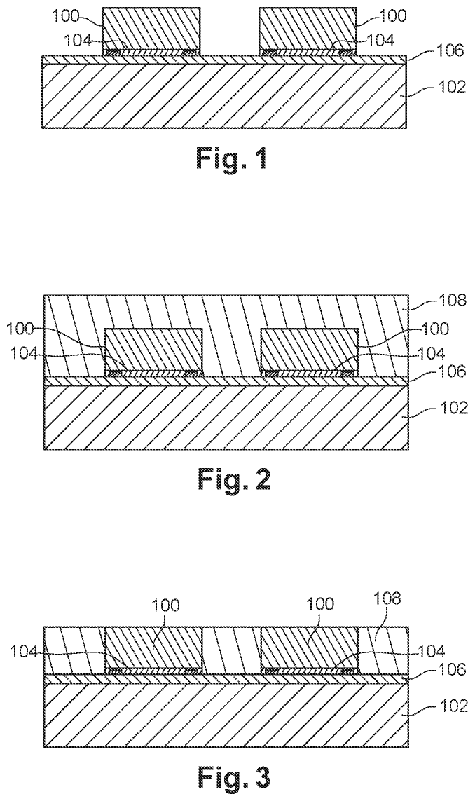

Afterwards, as shown in FIG. 2, the chips 100 are encapsulated in an encapsulation material 108. The encapsulation material 108 is herein deposited while covering the chips 100 as well as portions of the substrate 102 (and more specifically portions of the layer 106 in the example described herein) adjacent to the chips 100. For example, the encapsulation material 108 includes epoxy resin.

Afterwards, a flattening of the encapsulation material 108 with stoppage at least at one of the chips 100 is implemented (cf. FIG. 3). In the embodiment described herein, since the chips 100 have similar dimensions, flattening is stopped at second faces, opposite to the electrical connection faces, of each of the chips 100.

Afterwards, the chips 100 and the encapsulation material 108 are secured to a second substrate 116. Advantageously, this second substrate 116 is selected such that it has a good thermal conductivity, for example higher than or equal to 140 W/m·K, and a low coefficient of thermal expansion, for example lower than or equal to 14 ppm/K. For example, the second substrate 116 may include at least one among the following materials: monocrystalline or polycrystalline Si, monocrystalline or polycrystalline SiC, Cu, CuMo, CuW, AlN, AlSiC.

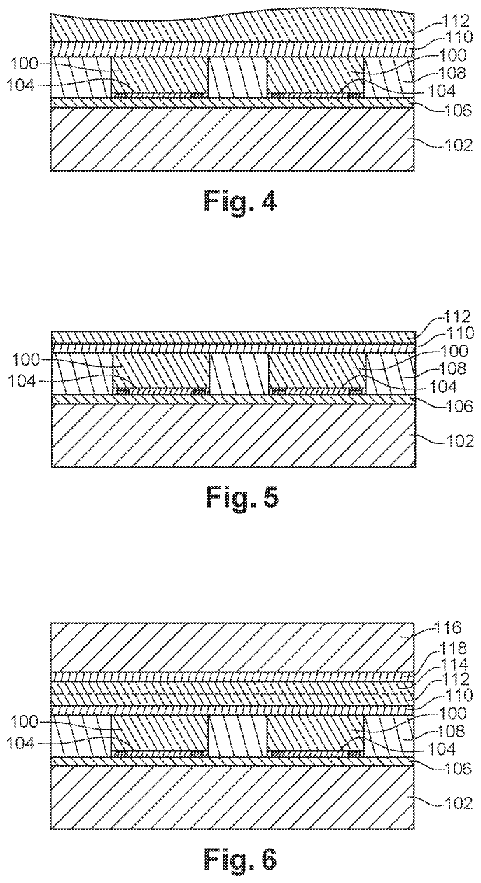

To achieve this attachment, at least one first metal layer 112 is made over the encapsulation material 108 and the chips 100. In the described particular embodiment, a metal underlayer, called first metal underlayer 110, corresponding for example to a titanium layer, is formed over the encapsulation material 108 and the upper faces of the chips 100. Afterwards, copper is deposited over the first metal underlayer 110 which herein serves as an adhesion layer for copper (cf. FIG. 4). Afterwards, copper is flattened to form the first metal layer 112 (cf. FIG. 5). If copper is deposited such that its roughness is compatible with the implementation of a direct bonding, it is possible to do without this flattening of the copper.

Concomitantly with this first metal layer 112, at least one second metal layer 114 is made over the second substrate 116. In the embodiment described herein, like when making the first metal layer 112, a metal underlayer, so-called second metal underlayer 118, corresponding for example to a titanium layer, is formed over a face of the second substrate 116. Afterwards, copper is deposited over the second metal underlayer 118 serving as an adhesion layer for this copper deposition, thereby forming the second metal layer 114. Like with first metal layer 112, flattening this copper may be implemented if the roughness of the deposited copper is too high and incompatible with the implementation of a direct bonding.

For example, the first and second metal layers 112, 114 have a thickness comprised between 50 nm and a few microns, and advantageously comprised between 200 nm and 500 nm.

Afterwards, the second substrate 116 is secured to the encapsulation material 108 and to the chips 100 by securing the first and second metal layers 112, 114 against one another. This attachment of the metal layers 112, 114 is obtained by implementing a direct bonding of these layers 112, 114 against one another. This direct bonding may be carried out at room temperature, or else be assisted by hot-pressing. A direct bonding at room temperature may be implemented when each of the bonding surfaces of the layers 112, 114 has a roughness lower than 0.5 nm RMS. A direct bonding assisted by hot-pressing may be implemented when each of the bonding surfaces of the layers 112, 114 has a roughness lower than 50 nm RMS. For example, such low roughnesses could be achieved by subjecting the bonding surfaces to a CMP (Chemical-Mechanical Polishing). Furthermore, securing the metal layers 112, 114 by direct bonding may be reinforced by implementing an annealing, after contact of the bonding surfaces against each other, for example at a temperature comprised between 200° C. and 400° C., and which allows reinforcing bonding thanks to a metal interdiffusion generated by this annealing (and a recrystallization when the metal layers 112, 114 include copper).

The structure obtained upon completion of this attachment is shown in FIG. 6.

In the above-described embodiment, the first and second metal layers 112, 114 correspond to copper layers secured by direct bonding against each other.

Alternatively, each of the first and second metal layers 112, 114 may correspond to a stack of a gold layer and of a copper layer. In this variant, for each of the first and second metal layers 112, 114, the gold layer is made after the copper layer so that securing the metal layers 112, 114 is obtained by carrying out a direct bonding of the two gold layers against one another. Afterwards, an annealing may be implemented at lower temperature, for example 150° C. For example, the thickness of each of the gold layers is equal to 50 nm. Optionally, each of the first and second metal layers 112, 114 may include a layer forming a diffusion barrier interposed between the copper layer and the gold layer. For example, such a barrier diffusion layer may include Ni or TiN and have a thickness comprised between 5 nm and 50 nm. In any case, for each of the first and second metal layers 112, 114, prior to the deposition of the gold layer and possibly before the deposition of the diffusion barrier over the copper layer, it is possible to implement flattening of the copper layer.

In another variant, the first and second metal layers 112, 114 may include gold rather than copper.

In any case, the first and second metal layers 112, 114 are made such that their roughness is low enough to enable direct bonding thereof, this low roughness being obtained either upon making of the first and second metal layers 112, 114, or after flattening of the first and second metal layers 112, 114.

Afterwards, the first substrate 102 is detached off the chips 100. In the embodiment described herein, this detachment is obtained by subjecting the layer 106 to a temperature or light radiation (depending on the nature of the layer 106) suppressing or considerably reducing the adhesive properties of this layer, thereby clearing the first substrate 102 from the rest of the structure.

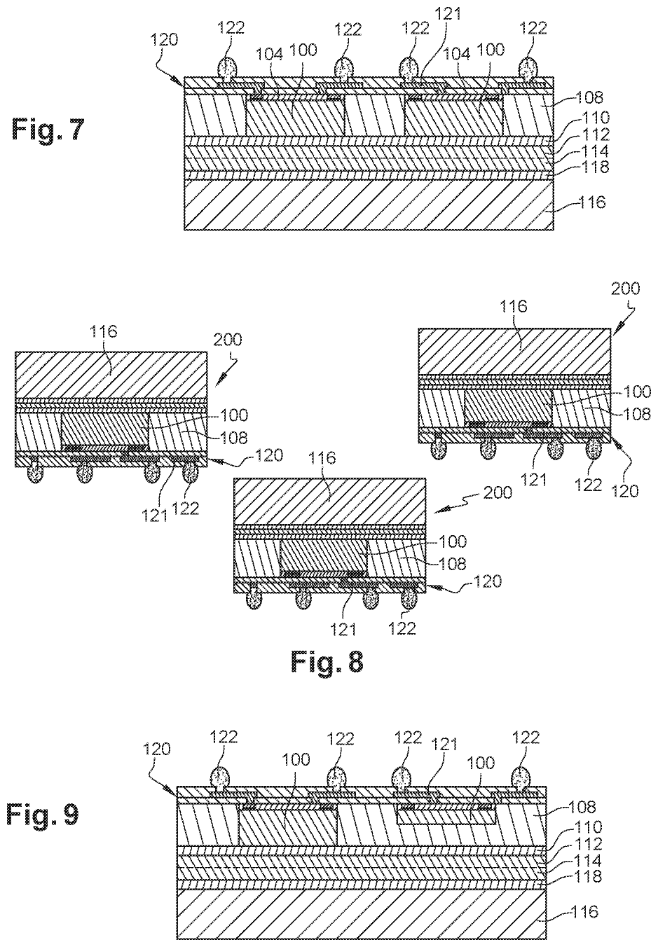

Afterwards, one or more redistribution layer(s) (RDL) 121, integrated within one or more interconnection level(s) 120, are made against the interconnection faces of the chips 100, then electrical interconnection elements 122, for example meltable material microbeads, are made over the redistribution layer(s) 121 such that these electrical interconnection elements 122 are electrically coupled to the interconnection pads 104 of the chips 100 via the redistribution layer(s) 121 (cf. FIG. 7). Other electrical interconnection elements that are not electrically coupled to the chips 100 may also be made over the redistribution layer(s) 121, these other elements being intended to serve only in mechanically holding the packaging that will be obtained.

Furthermore, in the case of a FOWLP-type packaging (as is the case in the example described herein), the electrical connection elements are distributed over a portion of the redistribution layer whose surface is larger than that of the electrical interconnection face of the electronic chip, which allows facilitating contact initiation of these elements. Afterwards, an operation of cutting the obtained structure may be implemented so as to singularize the packaged chips 100 (cf. FIG. 8). Each of the SiP-type packaged electronic devices obtained upon completion of this cut is referred to by the reference 200.

In the example of FIG. 8, each SiP device 200 includes one single chip 100. Nonetheless, each SiP device 200 may include several chips 100, depending on the functions intended to be filled by the SiP device 200. In this case, the electrical redistribution achieved by the redistribution layer(s) 121 also allows interconnecting the chips 100 of the same SiP device 200 together.

In the previously-described particular embodiment, the chips 100 affixed on the first substrate 102 have heights, or thicknesses, substantially similar to each other. Thus, flattening the encapsulation material 108 is stopped at the upper faces of the different chips 100. Alternatively, the chips 100 may have thicknesses that are different from each other. In this case, flattening the encapsulation material 108 is stopped at the upper face of the thicker chip(s) 100. An example of a structure obtained in such a variant is shown in FIG. 9, wherein one amongst the illustrated two chips 100 is thicker than the other one, flattening the encapsulation material 108 having been stopped at the upper face of the thicker chip 100. Thus, after cutting, the SiP device may include chips 100 having different thicknesses when these chips 100 belong to the same SiP device 200.

Alternatively, when the electronic chips 100 of the same SiP device 200 have different thicknesses, these chips 100 may be affixed on the first substrate 102 such that the upper faces of these chips 100 (faces opposite to those located on the side of the first substrate 102) are substantially aligned in the same plane.

In the previously-described embodiment, the heat dissipation is ensured by the second substrate 116 which is not structured.

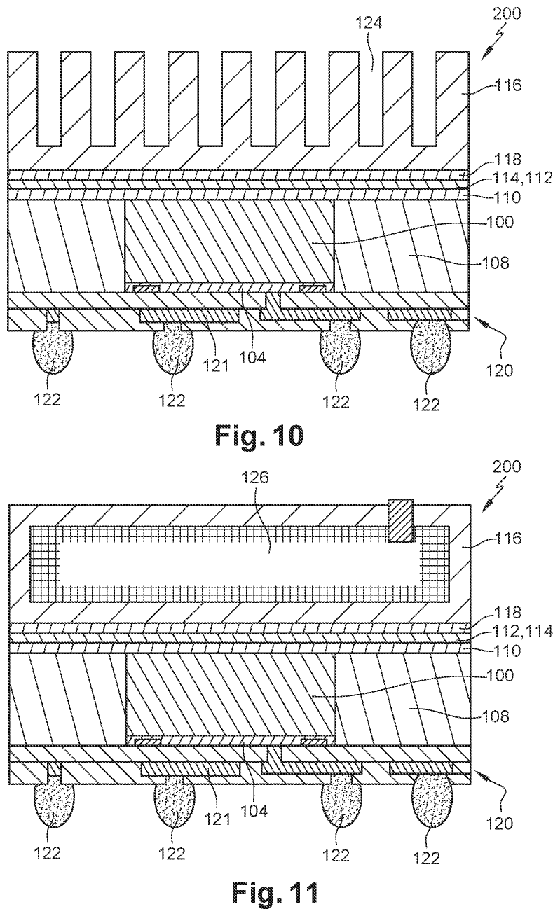

In an advantageous variant, before detachment of the first substrate 102, etching, for example reactive ion type etching (DRIE or “Deep Reactive Ion Etching”), of the second substrate 116 is implemented so that, upon completion of the method, the remaining portions of the second substrate 116, between which trenches 124 have been etched, form a heat-dissipating structure allowing for a greater heat dissipation because of the largest heat-exchange surface obtained thanks to the trenches 124. A device 200 obtained in such a variant is shown in FIG. 10.

In another advantageous variant, the substrate 116 may include integrated vapor chambers 126 (already present in the substrate 116 before securing thereof to the chips 100). Filling and sealing of these chambers 126 may be carried out after securing the substrate 116 to the chips 100. A device 200 obtained in such a variant is shown in FIG. 11.

The previously-described variants, wherein the second substrate 116 is used to form a heat-dissipating structure or integrates a vapor chamber, may be used when the device 200 includes several chips 100. When these chips 100 have different thicknesses (like in the example described before in connection with FIG. 9). The chip releasing heat the most is preferably made such that it corresponds to that one with the largest thickness so that it lies the closest to the second substrate 116 for a better heat dissipation.

In the previously-described different variants and examples, the second substrate 116 may be electrically coupled to the electronic chip(s) 100, for example to gain weight for the electronic chip(s) 100, and/or the second substrate 116 may further comprise at least one electromagnetic shielding layer. For example, the second substrate 116 may form a metal layer associated with vertical conductor elements crossing the encapsulation material, for example in the form of an array of copper-based studs made before positioning the chips 100 or of blocks positioned at the same time as the chips 100 and including, themselves, vertical conduction elements. In this case, the second substrate 116 may electrically contact these conductive elements thereby forming an electromagnetic cage. It is not necessary that the second substrate 116 be in electrical contact with the chip(s) 100.

1. A SiP-type electronic device, comprising at least:
an electronic chip provided with an electrical interconnection face;
a redistribution layer electrically coupled to the electrical interconnection face of the electronic chip;
electrical connection elements electrically coupled to the electronic chip by the redistribution layer which is arranged between the electronic chip and the electrical connection elements;
a first metal layer arranged on the side of a second face of the electronic chip, opposite to the electrical interconnection face, and secured to the second face of the electronic chip;
an encapsulation material arranged around the electronic chip, between the redistribution layer and the first metal layer;
a second metal layer comprising a first face secured by direct bonding to the first metal layer;
a substrate arranged against a second face, opposite to the first face, of the second metal layer.

2. The device according to claim 1, wherein the first and second metal layers include copper and/or gold.

3. The device according to claim 2, wherein each of the first and second metal layers includes a copper layer and a gold layer arranged against one another, the gold layers being secured by direct bonding against one another.

4. The device according to claim 1, wherein the substrate includes at least one among the following materials: silicon, SiC, Cu, CuMo, CuW, MN, AlSiC, and/or wherein the substrate includes at least one integrated vapor chamber, and/or wherein the substrate includes structures promoting heat exchanges with the external environment.

5. The device according to claim 1, wherein the electrical connection elements are distributed over a portion of the redistribution layer whose surface is larger than that of the electrical interconnection face of the electronic chip.

6. The device according to claim 1, wherein the substrate is electrically coupled to the electronic chip, and/or further comprising at least one electromagnetic shielding layer.

7. A method for making a SiP-type electronic device, comprising at least:
affixing an electronic chip over a first substrate such that an electrical interconnection face of the electronic chip is arranged on the side of the first substrate;
encapsulating the electronic chip in an encapsulation material;
making at least one first metal layer over the encapsulation material and the electronic chip;
making at least one second metal layer over a second substrate;
directly bonding the first and second metal layers against one another;
detaching the first substrate off the electronic chip and the encapsulation material;
making at least one redistribution layer electrically coupled to the electrical interconnection face of the electronic chip;
making electrical interconnection elements over the redistribution layer such that the electrical interconnection elements are electrically coupled to the electronic chip by the redistribution layer.

8. The method according to claim 7, wherein:
making the first metal layer includes at least depositing a first copper layer over the encapsulation material and the electronic chip, and
making the second metal layer includes at least depositing a second copper layer over the second substrate.

9. The method according to claim 8, wherein directly bonding the first and second metal layers against one another corresponds to directly bonding the first and second copper layers against one another.

10. The method according to claim 8, wherein:
making the first metal layer further includes depositing a first gold layer over the first copper layer, and
making the second metal layer further includes depositing a second gold layer over the second copper layer, and
directly bonding the first and second metal layers against one another corresponds to directly bonding the first and second gold layers against one another.

11. The method according to claim 7, wherein the encapsulation of the electronic chip includes at least depositing the encapsulation material over the electronic chip, then flattening the encapsulation material.

12. The method according to claim 7, wherein several electronic chips are simultaneously affixed on the first substrate such that an electrical interconnection face of each of the electronic chips is arranged on the side of the first substrate and wherein the other steps of the method are collectively implemented for all electronic chips, and further including, after making the electrical interconnection elements, a step of cutting the obtained structure so as to obtain several distinct SiP-type electronic devices each including one or more electronic chip(s).

13. The method according to claim 11, wherein, when the electronic chips have different thicknesses, flattening the encapsulation material is stopped at the electronic chip(s) having the largest thickness.

14. The method according to claim 7, further including, after making the electrical interconnection elements, etching the second substrate forming structures promoting heat exchanges with the external environment, and/or wherein the second substrate includes at least one integrated vapor chamber.
